(19) United States
(12) Patent Application Publication
(10) Pub. No.: US 2024/0092631 A1
(43) Pub. Date: Mar. 21, 2024

(54) MEMS SENSOR AND MANUFACTURING METHOD THEREOF

(71) Applicant: ROHM CO., LTD., Kyoto (JP)

(72) Inventors: Yoshiyuki INUI, Kyoto (JP); Toma FUJITA, Kyoto (JP)

(73) Assignee: ROHM CO., LTD., Kyoto (JP)

(21) Appl. No.: 18/463,708

(22) Filed: Sep. 8, 2023

(30) Foreign Application Priority Data
Sep. 15, 2022 (JP) 2022-147165

(51) Int. Cl. B81B 3/00; B81C 3/00

(52) U.S. Cl. CPC B81B 3/0051; B81C 3/001; B81B 2201/0235; B81B 2203/0315; B81B 2203/04; B81C 2203/019; B81C 2203/035

(57) ABSTRACT

The present disclosure provides a MEMS sensor. The MEMS sensor includes a first substrate having a cavity and a second substrate bonded to the first substrate. The first substrate is provided with an electrode movably disposed in the cavity and a sealed member coupling to the second substrate. The second substrate is provided with a stop member for restricting a movement of the electrode toward the second substrate and a sealing member coupling to the sealed member. The sealed member is formed by a first metal layer on the first substrate. The sealing member is formed by a second metal layer on the second substrate. A polycrystalline layer is formed on the stop member. The polycrystalline layer is disposed between the second substrate and the second metal layer.

### TECHNICAL FIELD

The present invention relates to a microelectromechanical systems (MEMS) sensor and a manufacturing method thereof.

### BACKGROUND

In commonly known art, MEMS sensors manufactured by means of semiconductor microfabrication techniques are used. Patent publication 1 discloses an MEMS sensor, which bonds a device-side substrate and a cover-side substrate by using a glass material to seal an electrode of a sensor element disposed on the device-side substrate.

The following metal bonding serving as a bonding technique for bonding a device-side substrate and a cover-side substrate is also commonly known. In the metal bonding, metal films respectively formed on the device-side substrate and the cover-side substrate are bonded. Compared to bonding by using a glass material, metal bonding is capable of achieving miniaturization of MEMS sensors.

### PRIOR ART DOCUMENT

[Patent publication]
[Patent publication 1] U.S. Pat. No. 8,319,254

### BRIEF DESCRIPTION OF THE DRAWINGS

FIG. 1 is a plan view of a microelectromechanical systems (MEMS) sensor according to a first embodiment of the present disclosure.

FIG. 2 is a plan view of a first substrate assembly.

FIG. 3 is an enlarged diagram of a main part of the first substrate assembly in FIG. 2.

FIG. 4 is a cross-section diagram of an MEMS sensor along the line IV-IV in FIG. 3.

FIG. 5 is a cross-section diagram of an MEMS sensor along the line V-V in FIG. 1.

FIG. 6 is a diagram of a first substrate assembly and a second substrate assembly before bonding.

FIG. 7 is a diagram for illustrating a method for manufacturing the first substrate assembly.

FIG. 8 is a diagram for illustrating a method for manufacturing the first substrate assembly.

FIG. 9 is a diagram for illustrating a method for manufacturing the first substrate assembly.

FIG. 10 is a diagram for illustrating a method for manufacturing the second substrate assembly.

FIG. 11 is a diagram of an MEMS sensor according to a second embodiment of the present disclosure.

FIG. 12 is a cross-section diagram of an MEMS sensor of the prior art.

### DETAILED DESCRIPTION OF THE EMBODIMENTS

Details of the embodiments of the present disclosure are given with the accompanying drawings below.

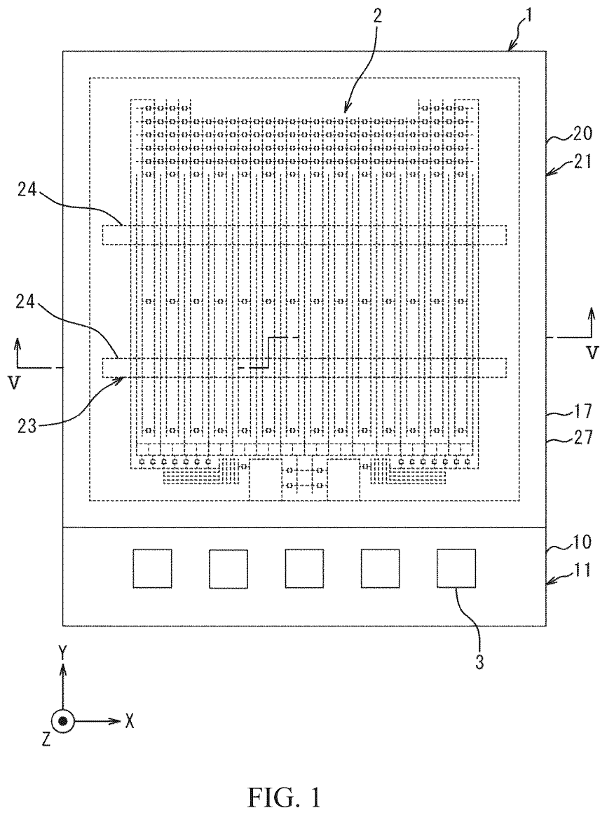

FIG. 1 shows a plan view of a microelectromechanical systems (MEMS) sensor according to a first embodiment of the present disclosure. As shown in FIG. 1, the MEMS sensor 1 according to the first embodiment of the present disclosure is a static capacitive acceleration sensor having a static capacitive acceleration sensor element serving as a sensor element 2. The MEMS sensor 1 includes: a first substrate assembly 11, having a first substrate 10, the first substrate 10 having the sensor element 2 and serving as a device-side substrate; and a second substrate assembly 21, having a second substrate 20, the second substrate 20 bonded to the first substrate 10 and serving as a cover-side substrate. The MEMS sensor 1 is manufactured by processing the first substrate 10 and the second substrate 20 by using a semiconductor microfabrication technique.

In the description below, a specific direction along surfaces of the first substrate 10 and the second substrate 20 is set as the X direction, a direction orthogonal to the X direction is set as the Y direction, and a thickness direction of the first substrate 10 and the second substrate 20 orthogonal to the X direction and the Y direction is set as the Z direction. FIG. 1 depicts the MEMS sensor 1 in which the second substrate 20 is bonded to the first substrate 10 on the top in the Z direction. In FIG. 1, wires formed at the first substrate 10 are omitted.

The sensor element 2 is a sensor element 2 that detects an acceleration acting in the X direction. However, the sensor element is not limited to the example above, and may be a sensor element that detects an acceleration acting in the Y direction or a sensor element that detects an acceleration acting in the Z direction.

The sensor element 2 is covered by the second substrate 20 by means of bonding the second substrate 20 to the first substrate 10 so as to be sealed. On the first substrate 10, there are multiple, and more specifically, five pads 3 disposed at intervals from one another in the X direction. The pads 3 are connected to, for example, external electronic parts. The pads 3 input electric signals to the sensor element 2 or output electric signals of the sensor element 2.

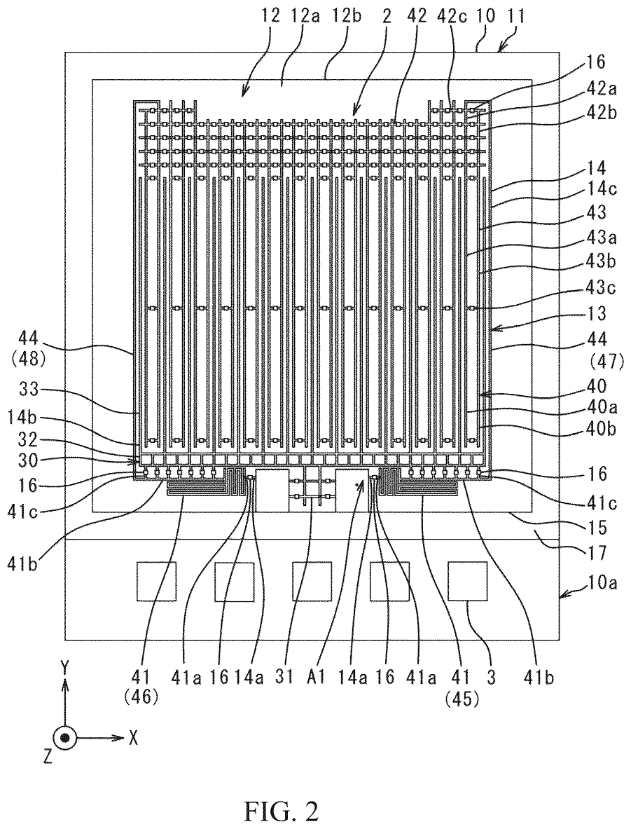

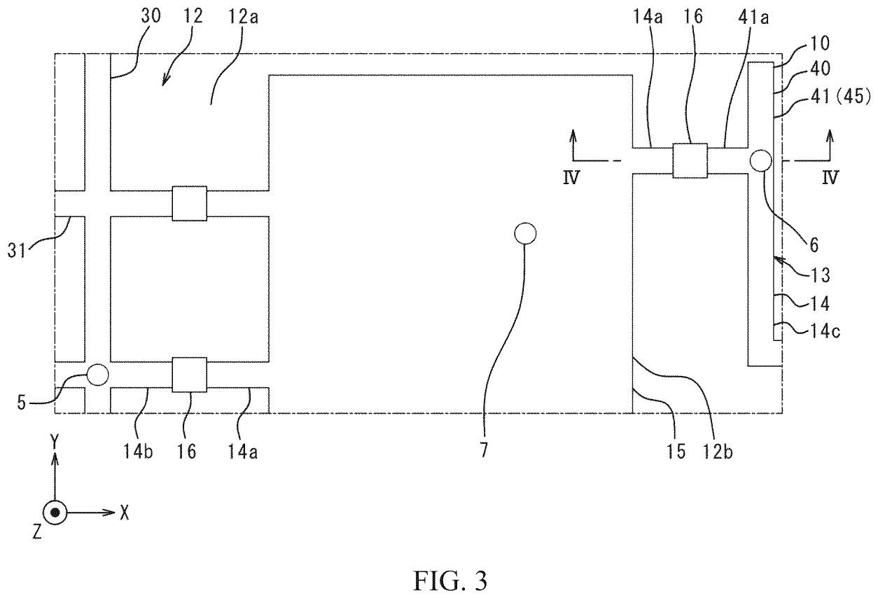

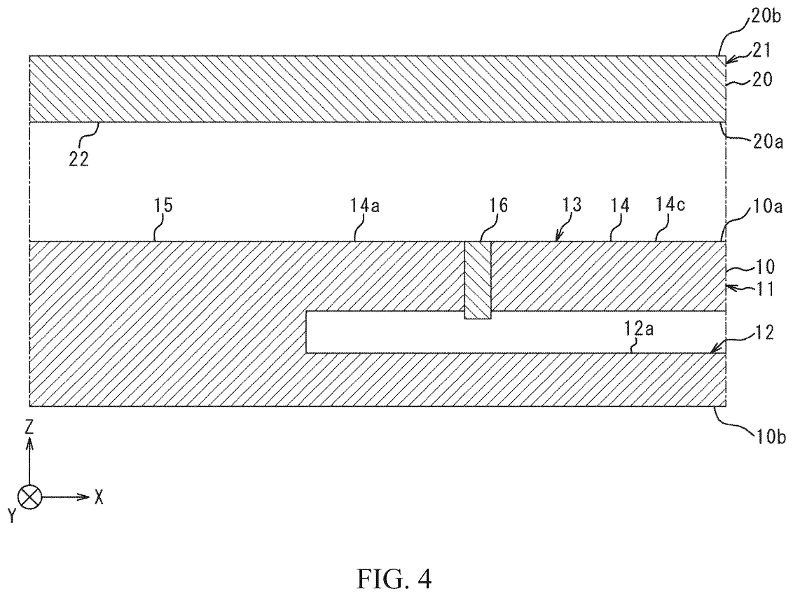

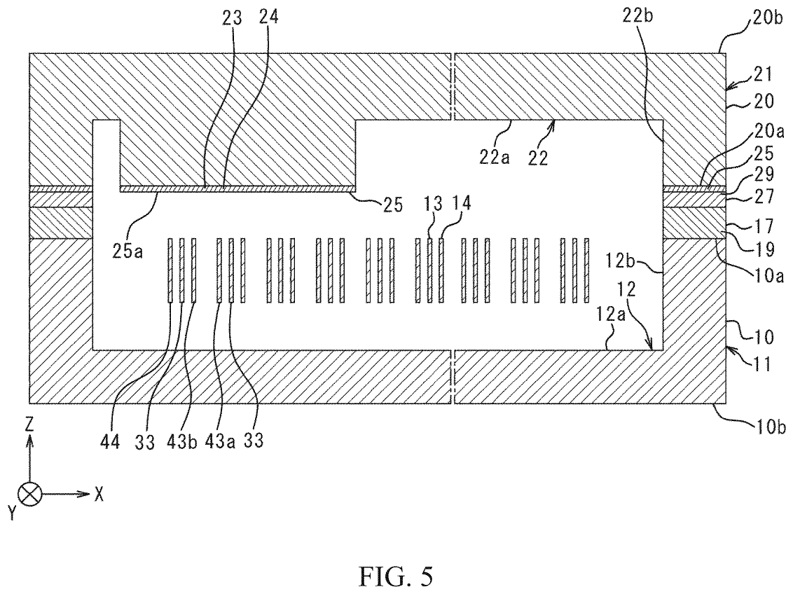

FIG. 2 shows a plan view of a first substrate assembly. FIG. 3 shows an enlarged diagram of a main part of the first substrate assembly in FIG. 2, with part Al in FIG. 2 enlarged. FIG. 4 shows a section diagram of an MEMS sensor along the line IV-IV in FIG. 3. FIG. 5 shows a section diagram of an MEMS sensor along the line V-V in FIG. 1.

As shown in FIG. 4 and FIG. 5, the first substrate assembly 11 includes the first substrate 10. The first substrate 10 has a first main surface 10a serving as an obverse side, and a second main surface 10b on a side opposite to the first main surface 10a and serving as a reverse side. The first substrate 10 is a rectangle in shape in a plan view, and the rectangle has two sides extending in the X direction and two sides extending in the Y direction. A conductive monocrystalline silicon substrate is used as the first substrate 10. The conductive monocrystalline silicon substrate is doped with impurities to provide conductivity, and has a resistivity of, for example, 1Ω·m to 5Ω·m. A surface roughness Sa (arithmetic mean roughness) of the first main surface 10a of the first substrate 10 is formed to be less than 1 nm.

As shown in FIG. 2, the first substrate 10 on a center side corresponding to the sensor element 2 has a cavity 12 exposing a portion of the first main surface 10a. For example, as shown in FIG. 5, the cavity 12 is formed by means of recessing as a substantially cuboid in the thickness direction of the first substrate 10 from the first main surface 10a, and has a bottom wall 12a and a sidewall 12b extending in the thickness direction of the first substrate 10 from the bottom wall 12a.

As shown in FIG. 3 and FIG. 4, the first substrate 10 has a beam portion 14 forming an electrode 13 of the sensor element 2 and a support portion 15 supporting the beam portion 14. The beam portion 14 is arranged in the cavity 12 of the first substrate 10, so as to be supported in a floating state by the support portion 15 in the cavity 12. The beam portion 14 is formed by a portion of the first substrate 10. The support portion 15 is formed as a substantially quadrilateral loop encircling a periphery of the sensor element 2 in the plan view, as shown in FIG. 2. An inner peripheral surface of the support portion 15 forms the sidewall 12b of the cavity 12.

The electrode 13 formed by the beam portion 14 is movably supported in a supported state by the support portion 15 in the cavity 12. The electrode 13 includes a fixed electrode 30, and a movable electrode 40 movable relative to the fixed electrode 30 in the X direction. The fixed electrode 30 and the movable electrode 40 are formed to have the same thickness in the thickness direction of the first substrate 10. As shown in FIG. 3, the beam portion 14 includes a support beam 14a, a fixed electrode beam 14b and a movable electrode beam 14c connected to the support portion 15.

The fixed electrode beam 14b and the movable electrode beam 14c are individually connected to the support beam 14a via separation portions 16. The separation portion 16 electrically separates and mechanically connects each of the fixed electrode beam 14b and the movable electrode beam 14c from and to the support beam 14a. The separation portion 16 contains silicon oxide, and is formed by silicon oxide serving as an insulation film.

As shown in FIG. 2 and FIG. 3, the fixed electrode 30 has a connecting portion 31 connected to the support beam 14a via the separation portion 16, a base portion 32 connected to the connecting portion 31, and multiple electrode portions 33 connected to the base portion 32 and forming a comb shape to extend in the Y direction. The connecting portion 31 is disposed as a grid shape in the plan view, and the base portion 32 is disposed as a step shape in the plan view. The multiple electrode portions 33 extend linearly in the Y direction from the base portion 32, and are equidistantly spaced in the X direction so as to be configured as a comb shape.

The movable electrode 40 includes a connecting portion 41 connected to the support beam 14a via the separation portion 16, a spring portion 44 connected to the connecting portion 41 and extending in the Y direction, a base portion 42 connected to the connecting portion 41 via the spring portion 41, and multiple electrode portions 43 connected to the base portion 42 and forming a comb shape to extend in the Y direction.

The connecting portion 41 includes a first connecting portion 45 configured on one side in the X direction and a second connecting portion 46 configured on the other side in the X direction. Each of the first connecting portion 45 and the second connecting portion 46 includes a first horizontal linear portion 41a linearly extending in the X direction toward an inside in the X direction of the sensor element 2 (referring to FIG. 3), a second horizontal linear portion 41b linearly extending in the X direction toward an outside in the X direction of the sensor element 2 (referring to FIG. 2), and multiple vertical linear portions 41c linearly extending in the Y direction toward one side in the Y direction of the sensor element 2 (referring to FIG. 2).

The first horizontal linear portion 41a of each of the first connecting portion 45 and the second connecting portion 46 is connected to the support beam 14a via the separation portion 16. The multiple vertical linear portions 41c of each of the first connecting portion 45 and the second connecting portion 46 are connected to the base portion 32 of the fixed electrode 30 via the separation portion 16, and the second horizontal linear portion 41b is connected to the spring portion 44. The separation portion 16 electrically separates and mechanically connects two adjacent regions. The separation portion 16 contains silicon oxide, and is formed by silicon oxide serving as an insulation film.

As shown in FIG. 2, the spring portion 44 includes a first spring portion 47 connected to the first connecting portion 45 and a second spring portion 48 connected to the second connecting portion 46. The first spring portion 47 and the second spring portion 48 are configured to be arranged on two sides in the X direction of the sensor element 2 and extend in the Y direction, and are movable in the X direction according to an acceleration acting in the X direction.

The base portion 42 includes multiple first vertical linear portions 42a and multiple second vertical linear portions 42b extending linearly in the Y direction in the plan view, and multiple horizontal linear portions 42b extending linearly in the X direction in the plan view, and is disposed as a grid shape. The first vertical linear portions 42a and the second vertical linear portions 42b are alternately arranged in the X direction, the first spring portion 47 is connected to one side in the Y direction of the first vertical linear portions 42a on one side in the X direction, and the second spring portion 48 is connected to one side in the Y direction of the second vertical linear portions 42b on the other side in the X direction.

The first vertical linear portions 42a and the second vertical linear portions 42b are electrically separated by the separation portion 16 disposed at the horizontal linear portion 42c. The multiple first vertical linear portions 42a are electrically connected via multiple contacts and wires disposed on the horizontal linear portions 42c. The multiple second vertical linear portions 42b are electrically connected via multiple contacts and wires disposed on the horizontal linear portions 42c.

The multiple electrode portions 43 extend linearly toward the other side in the Y direction from the base portion 42, and are equidistantly spaced in the X direction so as to be configured as a comb shape. The multiple electrode portions 43 include multiple first electrode portions 43a extending linearly in the Y direction from the first vertical linear portions 42a, and multiple second electrode portions 43b extending linearly in the Y direction from the second vertical linear portions 42b.

The first electrode portion 43a and the second electrode portion 43b serve as a pair configured between the electrode portions 33 of the fixed electrode 30, and each of the first electrode portion 43a and the second electrode portion 43b is configured to not contact with the opposite electrode portion 33 of the fixed electrode 30. One pair of the first electrode portion 43a and the second electrode portion 43b are connected by the multiple horizontal linear portions 43c extending linearly in the X direction and are electrically separated by the separation portion 16.

The movable electrode 40 includes a first movable electrode 40a having the first electrode portion 43a and a second movable electrode 40b having the second electrode portion 43b. The first movable electrode 40a includes the first electrode portion 43a, the first vertical linear portion 42a of the base 42, the first spring portion 47 and the first connecting portion 45. The second movable electrode 40b includes the second electrode portion 43b, the second vertical linear portion 42b of the base portion 42, the second spring portion 48 and the second connecting portion 46.

When an acceleration in the X direction acts on the sensor element 2, the electrode portion 43 of the movable electrode 40 moves relative to the electrode portion 33 of the fixed electrode 30 according to the acceleration, such that a gap between the electrode portion 33 and the electrode portion 43 changes, further changing static capacitances between the fixed electrode 30 and movable electrode 40, specifically the fixed electrode 30 and the first movable electrode 40a and between the fixed electrode 30 and the second movable electrode 40b. The MEMS sensor 1 can extract a change in the static capacitance between the fixed electrode 30 and the movable electrode 40 as an electric signal to detect the acceleration.

In the MEMS sensor 1, as shown in FIG. 3, a wire electrically connected to the pad 3 is connected to the fixed electrode 30 via a fixed electrode contact 5, a wire electrically connected to the pad 3 is connected to the first movable electrode 40a via a first movable electrode pad 6, and a wire electrically connected to the pad 3 is connected to the second movable electrode 40b via a second movable electrode contact. A wire electrically connected to the pad 3 is connected to the first substrate 10 via a substrate contact 7.

As shown in FIG. 4 and FIG. 5, the second substrate assembly 21 includes the second substrate 20. The second substrate 20 has a first main surface 20a serving as an obverse side, and a second main surface 20b on a side opposite to the first main surface 20a and serving as a reverse side. The second substrate 20 is a rectangle in shape in the plan view, and the rectangle has two sides extending in the X direction and two sides extending in the Y direction. A conductive monocrystalline silicon substrate is used as the second substrate 20. The conductive monocrystalline silicon substrate is doped with impurities to provide conductivity, and has a resistivity of, for example, 1Ω·m to 5Ω·m. The same as the first main surface 10a of the first substrate 10, a surface roughness Sa (arithmetic mean roughness) of the first main surface 20a of the second substrate 20 is formed to be less than 1 nm.

The second substrate 20 is bonded to the first substrate 10 to cover the cavity 12. A sealed member 17 coupling to the second substrate 20 is formed on the first substrate 10, and a sealing member 27 coupling to the sealed member 17 is formed on the second substrate 20.

As shown in FIG. 2, the sealed member 17 is configured around the cavity 12, and forms a loop of a substantially quadrilateral frame in the plan view. As shown in FIG. 5, the sealed member 17 is formed by an aluminum (Al) layer 19 serving as a first metal layer, wherein the Al layer 19 is formed on the first main surface 10a of the first substrate 10 by means of sputtering.

As shown in FIG. 1, the sealing member 27 is formed as a loop of a substantially quadrilateral frame corresponding to the sealed member 17 in the plan view. As shown in FIG. 5, the sealing member 27 is formed by a geranium (Ge) layer 29 serving as a second metal layer, wherein the Ge layer 29 is formed on the first main surface 20a of the second substrate 20 by means of evaporation.

The Ge layer 29 is formed on a polycrystalline silicon layer 25 serving as a polycrystalline layer, wherein the polycrystalline silicon layer 25 is formed on the second substrate 20 by means of chemical vapor deposition (CVD). The Al layer 19 is formed on the first substrate 10 when no polycrystalline silicon layer is provided. The Ge layer 29 is thinner than the Al layer 19. For example, the Al layer 19 is formed to have a thickness of 1000 nm, and the Ge layer 29 is formed to have a thickness of 400 nm. For example, the polycrystalline silicon layer 25 is formed to have a thickness of 100 nm. The polycrystalline silicon layer 25 is formed to have a surface roughness greater than those of the first main surface 10a of the first substrate 10 and the first main surface 20a of the second substrate 20. The surface roughness Sa (arithmetic mean roughness) of the polycrystalline silicon layer 25 is formed to be between 10 nm and 20 nm, for example.

The sealing member 27 formed on the second substrate 20 is coupled to the sealed member 17 formed on the first substrate 10. Accordingly, the cavity 12 disposed at the first substrate 10 is covered and hence sealed by the second substrate 20. The sealing member 27 of the second substrate 20 and the sealed member 17 of the first substrate 10 are coupled by means of metal bonding. By overlapping the first substrate 10 and the second substrate 20 and heating them at a predetermined temperature, for example, 430 degrees, in a predetermined pressurized state, the Al layer 19 is coupled with the Ge layer 29, and more specifically, joined by eutectic bonding.

As shown in FIG. 5, the second substrate 20 has a cavity 22 formed by means of recessing as a substantially cuboid in the thickness direction of the second substrate 20 from the first main surface 20a. The cavity 12 has a bottom wall 22a and a sidewall 22b extending in the thickness direction of the second substrate 20 from the bottom wall 22a.

A stop member 23 restricting a movement of the electrode 13 of the sensor element 2 toward the second substrate is disposed on the second substrate 20. The stop member 23 is formed to extend in the thickness direction of the second substrate 20 from the bottom wall 22a of the cavity 22 to the first main surface 20a of the second substrate 20. The stop member 23 may also be disposed to be closer to the side of the bottom wall 22a than the first main surface 20a of the second substrate 20.

As shown in FIG. 1, the stop member 23 includes two linear portions 24 separated in the Y direction and extending linearly in parallel in the X direction. The stop members 23 and the electrode 13 are formed to be opposite, and the two linear portions 24 are configured at an interval above the spring portion 44, the multiple electrode portions 33 of the fixed electrode 30 and the multiple electrode portions 43 of the movable electrode 40 extending in the Y direction.

The polycrystalline silicon layer 25 serving as a polycrystalline layer is formed on the stop member 23. In the MEMS sensor 1, a facing surface of the stop member 23 opposite to the electrode 13 is a facing surface 25a of the polycrystalline silicon layer 25 opposite to the electrode 13. When the electrode 13 disposed on the first substrate 10 overly flexes toward the second substrate and comes into contact with the stop member 23 of the second substrate 20, the electrode 13 comes into contact with the polycrystalline silicon layer 25 on the stop member 23.

Thus, by configuring the stop member 23 that restricts a movement of the electrode 13 above the electrode 13 by using the second substrate 20, the electrode 13 can be inhibited from overly flexing toward the second substrate 20 and hence from moving, thereby inhibiting breaking of the electrode 13.

In the MEMS sensor 1, the second substrate 20 is bonded to the first substrate 10 having the electrode 13, and the stop member 23 that restricts a movement of the electrode 13 is disposed on the second substrate 20. The sealed member 17 of the first substrate 10 is formed by the Al layer 19, the sealing member 27 of the second substrate 20 is formed by the Ge layer 29, the polycrystalline silicon layer 25 is formed on the stop member 23 of the second substrate 20, and the polycrystalline silicon layer 25 is formed between the second substrate 20 and the Ge layer 29.

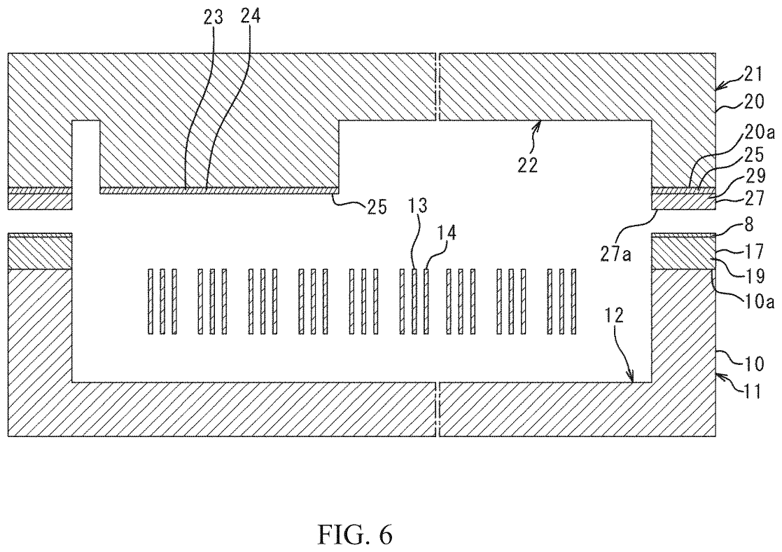

FIG. 6 shows a diagram of a first substrate assembly and a second substrate assembly before bonding. As shown in FIG. 6, the Ge layer 29 forming the sealing member 27 of the second substrate 20 is formed on the polycrystalline silicon layer 25, and the polycrystalline silicon layer 25 is formed on the second substrate 20. Compared to when no polycrystalline silicon layer is formed on the second substrate 20, the surface roughness Sa of the facing surface of the Ge layer 29 opposite to the sealed member 17 of the first substrate 10 is formed to be larger by the polycrystalline silicon layer 25.

FIG. 6 shows an Al oxide film 8 formed on the Al layer 19, and the sealed member 17 of the first substrate 10 is formed by the Al layer 19. As shown in FIG. 6, the Al oxide film 8 serving as a naturally oxide film is formed on the Al layer 19, and the Al oxide film 8 is formed to have a thickness of approximately 5 nm, for example. The surface roughness Sa of the Ge layer 29 is formed to be 10 nm to 20 nm, so as to allow Ge pass through the Al oxide film 8 by the polycrystalline silicon layer 25. Accordingly, even if the Al oxide film 8 is formed on sealed member 17, the Al oxide film 8 can be passed through to enable Al to come into contact with Ge to further performing metal bonding.

For metal bonding of the Al layer 19 and the Ge layer 29, more specifically, for eutectic bonding, compared to when the polycrystalline silicon layer 25 is not formed between the second substrate 20 and the Ge layer 29, the adhesion between the polycrystalline silicon layer 25 between the second substrate 20 and the Ge layer 29 and eutectic particles generated by an eutectic reaction is improved, thereby enhancing the bonding strength between the first substrate 10 and the second substrate 20.

As described above, the Ge layer 29 is thinner than the Al layer 19. Accordingly, when eutectic bonding is performed between the Al layer 19 and the Ge layer 29, the Al layer 19 causes an eutectic reaction only on the Ge layer side but does not cause any eutectic reaction on the non-Ge layer side. Thus, the polycrystalline silicon layer 25 is not formed between the first substrate 10 and the Al layer 19, hence enhancing the bonding strength between the first substrate 10 and the second substrate 20.

The polycrystalline silicon layer 25 is also formed on the stop member 23. Compared to when the polycrystalline silicon layer 25 is not formed, the stop member 23 causes the surface roughness Sa of the facing surface 25a of the polycrystalline silicon layer 25 opposite to the electrode 13 to be formed larger. Accordingly, compared to when a polycrystalline silicon layer is not formed on the stop member 23, the surface roughness Sa is increased and so that a contact area of the electrode 13 coming into contact with the stop member 23 is reduced, thereby inhibiting the electrode 13 from attaching to the stop member 23.

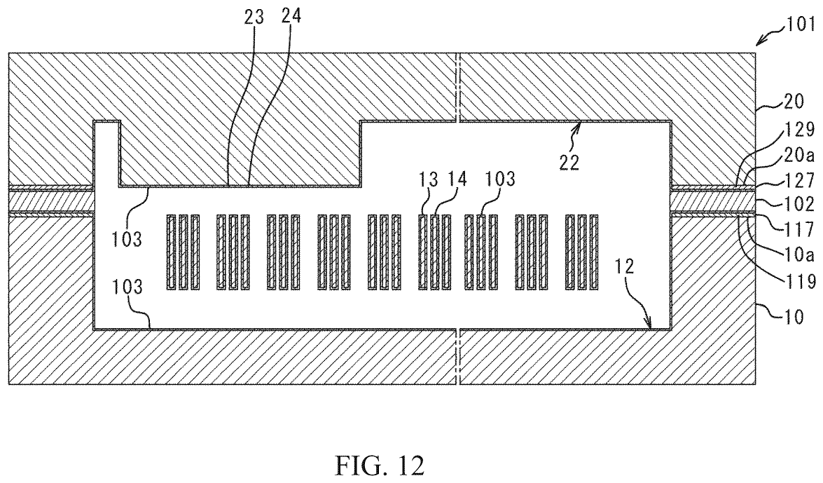

FIG. 12 shows a section diagram of an MEMS sensor of the prior art. FIG. 12 depicts a cross section the same as the cross section of the MEMS sensor 1 shown in FIG. 5. In an MEMS sensor 101 shown in FIG. 12, a sealing member 127 of the second substrate 20 is formed by an Al layer 129 formed on the second substrate 20, a sealed member 117 of the first substrate 10 is formed by an Al layer 119 formed on the first substrate 10, and the first substrate 10 and the second substrate 20 are bonded and thus sealed by a glass material 102 configured between the sealing member 127 and the sealed member 117.

Moreover, in the MEMS sensor 101 in FIG. 12, before the first substrate 10 and the second substrate 20 are bonded by the glass material 102, a non-adhesive water repellent coating layer 103 such as a fluororesin coating layer is formed on each of the first substrate 10 and the second substrate 20, and the water repellent coating layer 103 is formed on the electrode 13 and the stop member 23. In the MEMS sensor 101, the electrode 13 is inhibited from attaching to the stop member 23 by the water repellent coating layer 103, thereby bonding the first substrate 10 and the second substrate 20 by the glass material 102.

In the MEMS sensor 101, by bonding the first substrate 10 and the second substrate 20 by means of metal bonding, miniaturization can be achieved compared to bonding by using a glass material. Moreover, by forming the polycrystalline silicon layer 25 on the stop member 23 of the second substrate 20, the electrode 13 can be inhibited from attaching to the stop member 23. Even if the in situations in which metal bonding is performed on the first substrate 10 and the second substrate 20 and in which a non-adhesive fluororesin coating layer cannot be used at the stop member 23, the electrode 13 can still be inhibited from attaching to the stop member 23.

Next, a method for manufacturing the MEMS sensor 1 is described below.

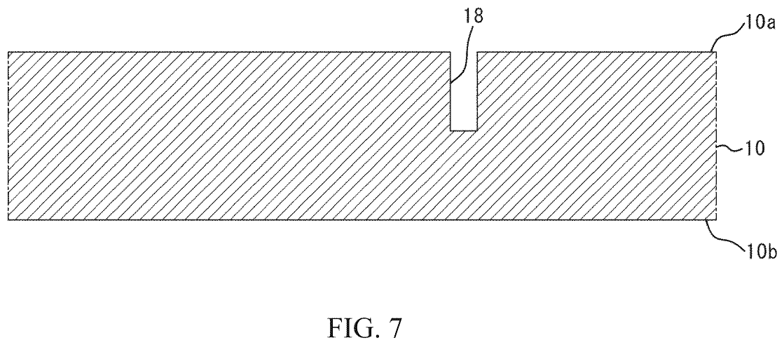

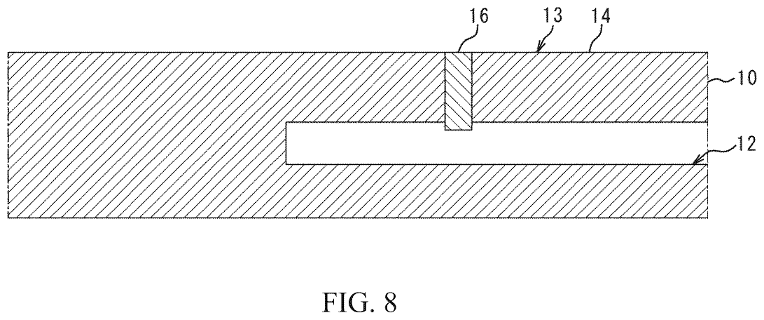

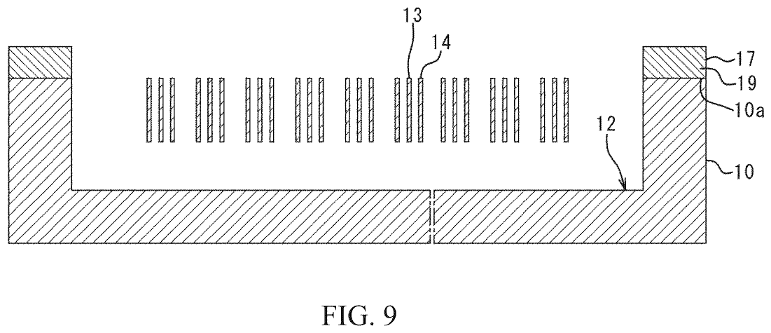

FIG. 7 to FIG. 9 are diagrams for illustrating a method for manufacturing a first substrate assembly. FIG. 7 and FIG. 8 represent cross sections of the first substrate assembly along the line IV-IV in FIG. 3, and FIG. 9 represents a cross section of the first substrate assembly along the line V-V in FIG. 2. In the manufacturing of the MEMS sensor 1, the first substrate 10 and the second substrate 20 serving as a monocrystalline substrate are prepared.

On the first substrate 10, as shown in FIG. 7, a portion corresponding to the separation portion 16 is removed to form a trench 18. Once the trench is formed, the trench 18 and the first main surface 10a of the first substrate 10 are in overall thermal oxidized, the separation portion 16 is formed by a silicon oxide film, and the silicon oxide film is formed on the first main surface 10a of the first substrate 10. Once the separation portion 16 is formed, the silicon oxide film on the first main surface 10a of the first substrate 10 is removed.

Next, the Al layer 19 is formed on a portion of the first substrate 10 corresponding to the sealing member 17 by means of sputtering. Moreover, the pads 3, contacts and wires are formed on the first substrate 10. Then, the first substrate 10 is patterned by means of photolithography and isotropic etching, and a trench is formed to leave the electrode 13 behind. Next, the trench is formed at a greater depth by means of isotropic etching, and etching is performed in a direction parallel to the first main surface 10a of the substrate 10 to form the cavity 12 exposing a portion of the first main surface 10a, as shown in FIG. 8 and FIG. 9. In addition, the beam portion 14 of the electrode 13 is formed to be configured in a floating state in the cavity 12, thereby manufacturing the first substrate assembly 11.

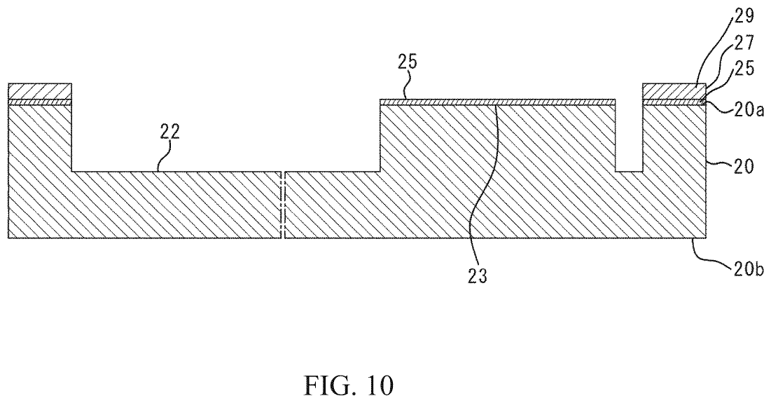

FIG. 10 shows a diagram for illustrating a method for manufacturing the second substrate assembly. At the second substrate 20, as shown in FIG. 10, the polycrystalline silicon layer 25 is formed on a portion of the second substrate 20 corresponding to the sealing member 27 and the stop member 23 by means of CVD method. Preferably, the polycrystalline silicon layer 25 formed on the portion of the second substrate 20 corresponding to the sealing member 27 and the polycrystalline silicon layer 25 formed on the portion of the second substrate 20 corresponding to the stop member 23 are formed simultaneously, or they may be formed not simultaneously.

Next, the Ge layer 29 is formed on a portion of the second substrate 20 corresponding to the sealing member 27 by means of sputtering. The Ge layer 29 is formed on the polycrystalline silicon layer 25, and the polycrystalline silicon layer 25 is formed on the second substrate 20.

Then, the sealing member 27 and the stop member 23 are patterned by means of photolithography and etching, the cavity 22 is formed on the second substrate 20, and the sealing member 27 and the stop member 23 are formed, thereby manufacturing the second substrate assembly 21.

The first substrate assembly 11 can be manufactured by the method above. The electrode 13 movably configured in the cavity 12 is formed on the first substrate 10 of the first substrate assembly 11, and the sealed member 17 is formed. The second substrate assembly 21 can also be manufactured. The stop member 23 is formed on the second substrate 20 of the second substrate assembly 21 to be opposite to the electrode 13, and the sealing member 27 is also formed.

Once the first substrate assembly 11 and the second substrate assembly 21 are manufactured, the sealing member 27 of the second substrate 20 and the sealed member 17 of the first substrate 10 are overlapped and bonded, and the second substrate 20 is bonded to the first substrate 10 to cover the cavity 12. The bonding between the first substrate assembly 11 and the second substrate assembly 21 is performed by eutectic bonding performed with heating to a predetermined temperature, for example, 430 degrees.

Thus, in the method for manufacturing the MEMS sensor 1 of the embodiment, the cavity 12 is formed in the first substrate 10 and the electrode 13 movably configured is formed in the cavity 12, the stop member 23 is formed on the second substrate 20 to restrict a movement of the electrode 13 toward the second substrate side, the first metal layer 19 is formed on the first substrate 10, the sealed member 17 is formed by the first metal layer 19, the second metal layer 29 is formed on the second substrate 20, the sealing member 27 is formed by the second metal layer 29, the polycrystalline silicon layer 25 is formed on the stop member 23 and between the second substrate 20 and the second metal layer 29, and the sealing member 27 is joined to the sealed member 17 so as to bond the second substrate 20 to the first substrate 10.

Accordingly, the electrode 13 movable in the cavity 12 is formed on the first substrate 10, the stop member 23 is formed on the second substrate 20 bonded to the first substrate 10, and the polycrystalline silicon layer 25 is formed on the stop member 23. Thus, compared to when a polycrystalline silicon layer is not formed on the stop member 23, the surface roughness is increased and so that a contact area of the electrode 13 coming into contact with the stop member 23 is reduced, thereby inhibiting the electrode 13 from attaching to the stop member 23.

Moreover, the first metal layer 19 is formed on the first substrate 10, the sealed member 17 is formed by the first metal layer 19, the second metal layer 29 is formed on the second substrate 20, the sealing member 27 bonded with the sealed member 17 is formed by the second metal layer 29, and the polycrystalline silicon layer 25 is formed between the second substrate 20 and the second metal layer 29. Thus, for metal bonding between the first metal layer 19 and the second metal layer 29, compared to when a polycrystalline silicon layer is not formed between the second substrate 20 and the second metal layer 29, the surface roughness is increased and hence the adhesion is improved, thereby enhancing the bonding strength between the first substrate 10 and the second substrate 20. When eutectic bonding is performed between the first metal layer 19 and the second metal layer 29, the adhesion between the polycrystalline silicon layer 25 between the second substrate 20 and the second metal layer 29 and eutectic particles generated by an eutectic reaction is improved, thereby enhancing the bonding strength between the first substrate 10 and the second substrate 20.

In the MEMS sensor 1, the beam portion 14 includes the support beam 14a, and the fixed electrode beam 14b and the movable electrode beam 14c are connected to the support beam 14a individually by the separation portion 16. However, the support beam 14a may be excluded, and the separation portion 16 is disposed at the support portion 15 instead.

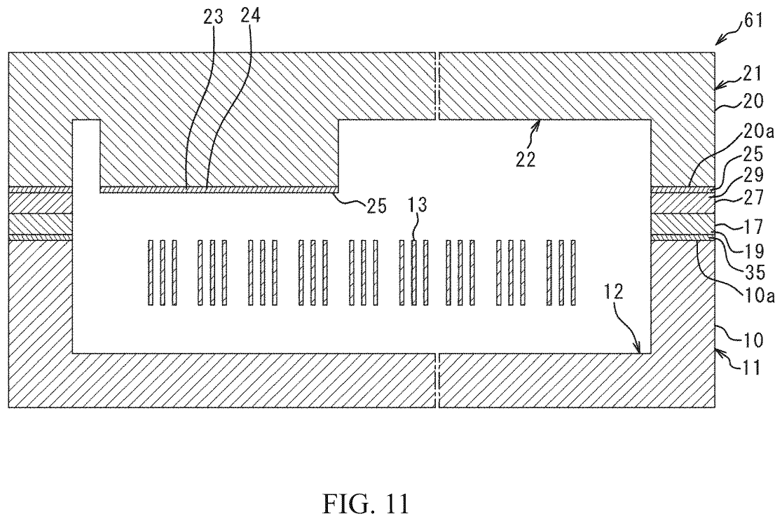

FIG. 11 shows a diagram of an MEMS sensor according to a second embodiment of the present disclosure, and depicts the first substrate assembly 11 and the second substrate assembly 21 before bonding. With respect to the MEMS sensor 1 of the first embodiment, in the MEMS sensor 61 of the second embodiment, the first metal layer 19 is formed to have a thickness equal to that of the second metal layer 29, and a polycrystalline layer is formed between the first substrate 10 and the first metal layer 19. The description for the same configuration details are omitted herein.

The same as the MEMS sensor 1 of the first embodiment, in the MEMS sensor 61 of the second embodiment, the second substrate 20 is bonded to the first substrate 10 having the electrode 13, and the stop member 23 that restricts a movement of the electrode 13 is disposed on the second substrate 20. The sealed member 17 of the first substrate 10 is formed by the Al layer 19, the sealing member 27 of the second substrate 20 is formed by the Ge layer 29, the polycrystalline silicon layer 25 is formed on the stop member 23 of the second substrate 20, and the polycrystalline silicon layer 25 is formed between the second substrate 20 and the Ge layer 29.

In the MEMS sensor 61, the Al layer 19 forming the sealed member 17 is formed to have a thickness equal to that of the Ge layer 29 forming the sealing member 27, and a polycrystalline silicon layer 35 serving as a polycrystalline layer is formed between the first substrate 10 and the Al layer 19. The Al layer 19 is formed on the polycrystalline silicon layer 35, and the polycrystalline silicon layer 35 is formed on the first substrate 10 by means of CVD method. Each of the Al layer 19 and the Ge layer 29 is formed to have a thickness of, for example, 500 nm. The polycrystalline silicon layers 25 and 35 are formed to have a thickness of, for example, 100 nm.

In the MEMS sensor 61, the Al layer 19 forming the sealed member 17 is formed to have a thickness equal to that of the Ge layer 29 forming the sealing member 27, the polycrystalline silicon layer 25 is formed between the second substrate 20 and the Ge layer 29, and the polycrystalline silicon layer 35 is formed between the first substrate 10 and the Al layer 19.

When the Al layer 19 forming the sealed member 17 is formed to have a thickness equal to that of the Ge layer 29 forming the sealing member 27 and eutectic bonding is performed between the Al layer 19 and the Ge layer 29, the adhesion between the polycrystalline silicon layer 25 and the eutectic particles generated from the liquid phase by an eutectic reaction can be improved, and the adhesion between the polycrystalline silicon layer 35 and the eutectic particles generated from the liquid phase by an eutectic reaction can also be improved, thereby enhancing the bonding strength between the first substrate 10 and the second substrate 20.

In the MEMS sensors 1 and 61, the Al layer 19 is used as the first metal layer forming the sealed member 17, and the Ge layer 29 is used as the second metal layer forming the sealing member 27. However, a first metal and a second metal different from Al and Ge but also perform an eutectic reaction can also be used as the first metal layer and the second metal layer.

In the MEMS sensors 1 and 61, the first metal layer 19, the second metal layer 29, and the polycrystalline silicon layers 25 and 35 are respectively formed by means of sputtering, evaporation and CVD, or may be formed by other means. The MEMS sensors 1 and 61 are static capacitive acceleration sensors, and may also be applied to other sensors in which an electrode is movably configured.

Thus, in the MEMS sensors 1 and 61 of the embodiments, the electrode 13 is movably disposed on the first substrate 10, the stop member 23 is disposed on the second substrate 20 bonded to the first substrate 10, and the polycrystalline silicon layer 25 is formed on the stop member 23. Accordingly, compared to when a polycrystalline layer is not formed on the stop member 23, the surface roughness is increased and so that a contact area of the electrode 13 coming into contact with the stop member 23 is reduced, thereby inhibiting the electrode 13 from attaching to the stop member 23. Even if in a situation in which a non-adhesive fluororesin coating layer cannot be used at the stop member 23, the electrode 13 can still be inhibited from attaching to the stop member 23.

Moreover, the sealed member 17 is formed by the first metal layer 19 on the first substrate 10, the sealing member 27 bonding to the sealing member 17 is formed by the second metal layer 29 on the second substrate 20, and the polycrystalline silicon layer 25 is formed between the second substrate 20 and the second metal layer 29. Accordingly, when metal bonding is performed between the first metal layer 19 and the second metal layer 29, compared to when a polycrystalline layer is not formed between the second substrate 20 and the second metal layer 29, the surface roughness is increased to improve the adhesion, thereby enhancing the bonding strength between the first substrate 10 and the second substrate 20.

Thus, in the MEMS sensors 1 and 61, by bonding the second substrate 20 to the first substrate 10 having the electrode 13 and disposing the stop member 23 that restricts a movement of the electrode 13 on the second substrate 20, the electrode 13 can be inhibited from attaching to the stop member 23, and the bonding strength between the first substrate 10 and the second substrate 20 can be enhanced.

Moreover, the second substrate 20 is a monocrystalline silicon substrate, and the polycrystalline layer 25 is a polycrystalline silicon layer. Accordingly, in the MEMS sensors 1 and 61, by forming the polycrystalline silicon layer 25 on the stop member 23 of the second substrate 20 serving as a monocrystalline silicon substrate, and forming the polycrystalline silicon layer 25 between the second substrate 20 serving as a monocrystalline silicon substrate and the second metal layer 29 forming the sealing member 27, the electrode 13 can be inhibited from attaching to the stop member 23, and the bonding strength between the first substrate 10 and the second substrate 20 can be enhanced.

In addition, the sealed member 17 and the sealing member 27 are joined by eutectic bonding between the first metal layer 19 and the second metal layer 29. Accordingly, when eutectic bonding is performed between the first metal layer 19 and the second metal layer 29, compared to when a polycrystalline layer is not formed between the second substrate 20 and the second metal layer 29, the adhesion between the polycrystalline silicon layer 25 between the second substrate 20 and the second metal layer 29 and eutectic particles generated by an eutectic reaction is improved, thereby enhancing the bonding strength between the first substrate 10 and the second substrate 20.

Moreover, the second metal layer 29 is thinner than the first metal layer 19. Accordingly, when eutectic bonding is performed between the first metal layer 19 and the second metal layer 29, a non-second metal layer side of the first metal layer 19 does not undergo an eutectic reaction but only the second metal layer side undergoes an eutectic reaction, such that the adhesion strength between the first substrate 10 and the second substrate 20 is enhanced without forming any polycrystalline layer between the first substrate 10 and the first metal layer 19.

Moreover, the first metal layer 19 is the Al layer 19, and the second metal layer 29 is the Ge layer 29. Accordingly, in the MEMS sensors 1 and 61, by performing eutectic bonding between the Al layer 19 and the Ge layer 29 to bond the first substrate 10 to the second substrate 20, the bonding strength between the first substrate 10 and the second substrate 20 can be enhanced.

Moreover, the sensor element 2 is the capacitive acceleration sensor element 2. Accordingly, in the MEMS sensors 1 and 61 having the static capacitive acceleration sensor 2, the electrode 13 can be inhibited from attaching to the stop member 23, and the bonding strength between the first substrate 10 and the second substrate 20 can be enhanced.

Moreover, in the MEMS sensors 1 and 61 of the embodiments, the electrode 13 movable in the cavity 12 is formed on the first substrate 10, the stop member 23 is formed on the second substrate 20 bonded to the first substrate 10 to cover the cavity 12, and the polycrystalline silicon layer 25 is formed on the stop member 23. Accordingly, compared to when the polycrystalline silicon layer 25 is not formed on the stop member 23, the surface roughness is increased and so that a contact area of the electrode 13 coming into contact with the stop member 23 is reduced, thereby inhibiting the electrode 13 from attaching to the stop member 23. Even if in a situation in which a non-adhesive fluororesin coating layer cannot be used at the stop member 23, the electrode 13 can still be inhibited from attaching to the stop member 23.

Moreover, the first metal layer 19 is formed on the first substrate 10, the sealed member 17 is formed by the first metal layer 19, the second metal layer 29 is formed on the second substrate 20, the sealing member 27 bonding to the sealed member 17 is formed by the second metal layer 29, and the polycrystalline silicon layer 25 is formed between the second substrate 20 and the second metal layer 29. Accordingly, when metal bonding is performed between the first metal layer 19 and the second metal layer 29, compared to when a polycrystalline layer is not formed between the second substrate 20 and the second metal layer 29, the surface roughness is increased to improve the adhesion, thereby enhancing the bonding strength between the first substrate 10 and the second substrate 20.

Thus, in the MEMS sensors 1 and 61, by bonding the second substrate 20 to the first substrate 10 having the electrode 13 and disposing the stop member 23 that restricts a movement of the electrode 13 on the second substrate 20, the electrode 13 can be inhibited from attaching to the stop member 23, and the bonding strength between the first substrate 10 and the second substrate 20 can be enhanced.

The present disclosure is not limited to the non-limiting embodiments above, and various improvements and design changes may be implemented without departing from the scope of the technical inventive subject of the present disclosure.

### [Note 1]

A microelectromechanical systems (MEMS) sensor, comprising:
a first substrate, including a cavity having a portion exposing a surface of the first substrate; and
a second substrate, bonded to the first substrate to cover the cavity,
wherein an electrode of a sensor element movably arranged in the cavity and a sealed member coupling to the second substrate are disposed on the first substrate,
a stop member restricting a movement of the electrode toward the second substrate and a sealing member coupling to the sealed member are disposed on the second substrate,
the sealed member is formed by a first metal layer on the first substrate,
the sealing member is formed by a second metal layer on the second substrate,
a polycrystalline layer is formed on the stop member, and the polycrystalline layer is formed between the second substrate and the second metal layer.

### [Note 2]

The MEMS sensor according to note 1, wherein the second substrate is a monocrystalline silicon substrate, and the polycrystalline layer is a polycrystalline silicon layer.

### [Note 3]

The MEMS sensor according to note 1 or 2, wherein the sealed member and the sealing member are joined by eutectic bonding between the first metal layer and the second metal layer.

### [Note 4]

The MEMS sensor according to any one of notes 1 to 3, wherein the second metal layer is thinner than the first metal layer.

### [Note 5]

The MEMS sensor according to any one of notes 1 to 4, wherein the first metal layer is an aluminum (Al) layer, and the second metal layer is a germanium (Ge) layer.

### [Note 6]

The MEMS sensor according to any one of notes 1 to 5, wherein the sensor element is a capacitive acceleration sensor element.

### [Note 7]

A method for manufacturing an MEMS sensor, comprising:
forming a cavity in which a portion of the cavity exposes a surface of the first substrate;
forming an electrode of a sensor element movably arranged in the cavity on the first substrate;
forming a stop member on a second substrate bonded to the first substrate to cover the cavity, wherein the stop member is for restricting a movement of the electrode toward the second substrate;
forming a first metal layer on the first substrate to form a sealed member bonding to the second substrate;
forming a second metal layer on the second substrate to form a sealing member bonding to the sealed member;
forming a polycrystalline layer on the stop member and between the second substrate and the second metal layer; and
joining the sealing member to the sealed member such that the second substrate is joined to the first substrate.

### [Note 8]

The method for manufacturing an MEMS sensor according to note 7, wherein the second substrate is a monocrystalline silicon substrate, and the polycrystalline layer is a polycrystalline silicon layer.

### [Note 9]

The method for manufacturing an MEMS sensor according to note 7 or 8, wherein the sealed member and the sealing member are joined by eutectic bonding between the first metal layer and the second metal layer.

### [Note 10]

The method for manufacturing an MEMS sensor according to any one of notes 7 to 9, wherein the second metal layer is thinner than the first metal layer.

### [Note 11]

The method for manufacturing an MEMS sensor according to any one of notes 7 to 10, wherein the first metal layer is an aluminum (Al) layer, and the second metal layer is a germanium (Ge) layer.

### [Note 12]

The method for manufacturing an MEMS sensor according to any one of notes 7 to 11, wherein the sensor element is a capacitive acceleration sensor element.

1. A MEMS sensor, comprising:
a first substrate, including a cavity having a portion exposing a surface of the first substrate; and
a second substrate, bonded to the first substrate to cover the cavity, wherein
an electrode of a sensor element movably arranged in the cavity and a sealed member coupling to the second substrate, wherein the electrode and the sealed member are disposed on the first substrate,
a stop member restricting a movement of the electrode toward the second substrate and a sealing member coupling to the sealed member,
the sealed member is formed by a first metal layer on the first substrate,
the sealing member is formed by a second metal layer on the second substrate, and
a polycrystalline layer is formed on the stop member, and the polycrystalline layer is formed between the second substrate and the second metal layer.

2. The MEMS sensor of claim 1, wherein the second substrate is a monocrystalline silicon substrate, and the polycrystalline layer is a polycrystalline silicon layer.

3. The MEMS sensor of claim 1, wherein the sealed member and the sealing member are joined by eutectic bonding between the first metal layer and the second metal layer.

4. The MEMS sensor of claim 1, wherein the second metal layer is thinner than the first metal layer.

5. The MEMS sensor of claim 1, wherein the first metal layer is an aluminum (Al) layer, and the second metal layer is a germanium (Ge) layer.

6. The MEMS sensor of claim 1, wherein the sensor element is a capacitive acceleration sensor element.

7. A method for manufacturing a MEMS sensor, comprising:
forming a cavity in which a portion of the cavity exposes a surface of the first substrate;
forming an electrode of a sensor element movably arranged in the cavity on the first substrate;
forming a stop member on a second substrate bonded to the first substrate to cover the cavity, wherein the stop member is for restricting a movement of the electrode toward the second substrate;
forming a first metal layer on the first substrate to form a sealed member bonding to the second substrate;
forming a second metal layer on the second substrate to form a sealing member bonding to the sealed member;
forming a polycrystalline layer on the stop member and between the second substrate and the second metal layer; and
joining the sealing member to the sealed member such that the second substrate is joined to the first substrate.

8. The method of claim 7, wherein the second substrate is a monocrystalline silicon substrate, and the polycrystalline layer is a polycrystalline silicon layer.

9. The method of claim 7, wherein the sealed member and the sealing member are joined by eutectic bonding between the first metal layer and the second metal layer.

10. The method of claim 7, wherein the second metal layer is thinner than the first metal layer.

11. The method of claim 7, wherein the first metal layer is an Al layer, and the second metal layer is a Ge layer.

12. The method of claim 7, wherein the sensor element is a capacitive acceleration sensor element.
